(19) United States
(12) Patent Application Publication
(10) Pub. No.: US 2024/0305059 A1
(43) Pub. Date: Sep. 12, 2024

(54) OPTICAL MODULE AND METHOD OF MANUFACTURING OPTICAL MODULE

(71) Applicant: Mitsubishi Electric Corporation, Chiyoda-ku, Tokyo (JP)

(72) Inventors: Daisuke MORITA, Tokyo (JP); Tomohiro KYOTO, Tokyo (JP); Masato KAWASAKI, Tokyo (JP)

(73) Assignee: Mitsubishi Electric Corporation, Chiyoda-ku, Tokyo (JP)

(21) Appl. No.: 18/575,376

(22) PCT Filed: Jul. 29, 2022
(86) PCT No.: PCT/JP2022/029340

§ 371 Date: Dec. 29, 2023

(30) Foreign Application Priority Data
Aug. 26, 2021 (JP) 2021-137721

(51) Int. Cl. H01S 5/02253; G01B 11/27; H01S 5/0239

(52) U.S. Cl. CPC H01S 5/02253; G01B 11/27; H01S 5/0239

(57) ABSTRACT

An optical module includes: a lens unit including a collimating lens array that collimates a plurality of beams output from a multi-emitter semiconductor laser bar including a plurality of emission points; and element units including respective optical elements disposed in front of the lens unit in a direction of propagation of the beams, in which the element units further include respective holding members that hold the respective optical elements. An orientation of a curve of the collimating lens array and orientations of curves of the optical elements are aligned with an orientation of a curve of a line connecting the plurality of emission points, and the holding members are joined by corresponding third joining members in the direction of propagation.

### FIELD

The present disclosure relates to an optical module that outputs laser light and a method of manufacturing the optical module.

### BACKGROUND

Conventionally, an optical module that outputs laser light has been used to machine a workpiece. For example, an optical module has been proposed that includes a multi-emitter semiconductor laser bar including a plurality of emission points and a collimating lens array for collimating a plurality of beams output from the multi-emitter semiconductor laser bar. Conventionally, a lens component has also been proposed that includes a plate-shaped portion, a lens portion provided on a lower surface of the plate-shaped portion, and a pair of rib portions extending along the plate-shaped portion with the plate-shaped portion interposed therebetween (see, for example, Patent Literature 1).

### CITATION LIST

### Patent Literature

Patent Literature 1 Japanese Patent No. 5899925

### SUMMARY OF INVENTION

### Problem to be Solved by the Invention

As described above, the optical module is known that includes the multi-emitter semiconductor laser bar including the plurality of emission points and the collimating lens array for collimating the plurality of beams output from the multi-emitter semiconductor laser bar. In the optical module, when the orientation of a curve of a line connecting the plurality of emission points to each other is different from the orientation of a curve of the collimating lens array, the plurality of beams output from the multi-emitter semiconductor laser bar do not travel in straight lines. When the plurality of beams do not travel in straight lines, the amount of laser light that can be used for machining decreases. The decrease in the amount of laser light makes machining of the workpiece difficult.

Patent Literature 1 discloses a technique for preventing deformation on the side of the lens, but even when the technique disclosed in Patent Literature 1 is taken into consideration, a situation occurs in which the orientation of the curve of the line connecting the plurality of emission points to each other is different from the orientation of the curve of the collimating lens array in the optical module. That is, in the conventional technique, a loss of propagation of laser light output from the optical module may occur.

The present disclosure has been made in view of the above, and an object of the present disclosure is to provide an optical module that prevents the occurrence of a loss of propagation of laser light that is output therefrom.

### Means to Solve the Problem

In order to solve the above problem and achieve the object, an optical module according to the present disclosure includes: a multi-emitter semiconductor laser bar including a plurality of emission points; a lens unit including a collimating lens array for collimating a plurality of beams output from the multi-emitter semiconductor laser bar; and one or a plurality of element units including an optical element disposed in front of the lens unit in a direction of propagation of the plurality of beams. Each of the element units further includes a plurality of holding members that holds the optical element. An orientation of a curve of the collimating lens array on a plane that is orthogonal to the direction of propagation and includes the collimating lens array is aligned with an orientation of a curve of a line connecting the plurality of emission points on a plane that is orthogonal to the direction of propagation and includes the plurality of emission points. An orientation of a curve of each of the optical elements on a plane that is orthogonal to the direction of propagation and includes the optical elements is aligned with the orientation of the curve of the line connecting the plurality of emission points, and each of the holding members is joined in the direction of propagation by a joining material.

### Effects of the Invention

The optical module according to the present disclosure has an effect of being able to prevent the occurrence of the loss of propagation of the laser light that is output therefrom.

### BRIEF DESCRIPTION OF DRAWINGS

FIG. 1 is a diagram schematically illustrating a side face of an optical module according to a first embodiment.

FIG. 2 is a diagram schematically illustrating a plane of the optical module according to the first embodiment.

FIG. 3 is a diagram schematically illustrating a front face of the optical module according to the first embodiment.

FIG. 4 is a set of diagrams for explaining a method of manufacturing an optical module according to the first embodiment.

FIG. 5 is a diagram schematically illustrating a side face of an optical module according to a second embodiment.

FIG. 6 is a diagram schematically illustrating a front face of the optical module according to the second embodiment,

FIG. 7 is a diagram schematically illustrating a side face of an optical module according to a third embodiment.

FIG. 8 is a flowchart illustrating an example of a procedure for a method of manufacturing an optical module according to the third embodiment.

FIG. 9 is a first diagram for explaining an effect obtained by the optical module according to the third embodiment.

FIG. 10 is a second diagram for explaining an effect obtained by the optical module according to the third embodiment.

FIG. 11 is a diagram schematically illustrating a side face of an optical module according to a fourth embodiment.

FIG. 12 is a diagram schematically illustrating a plane of the optical module according to the fourth embodiment.

### DESCRIPTION OF EMBODIMENTS

Hereinafter, an optical module and a method of manufacturing the optical module according to embodiments will be described in detail with reference to the drawings.

### First Embodiment

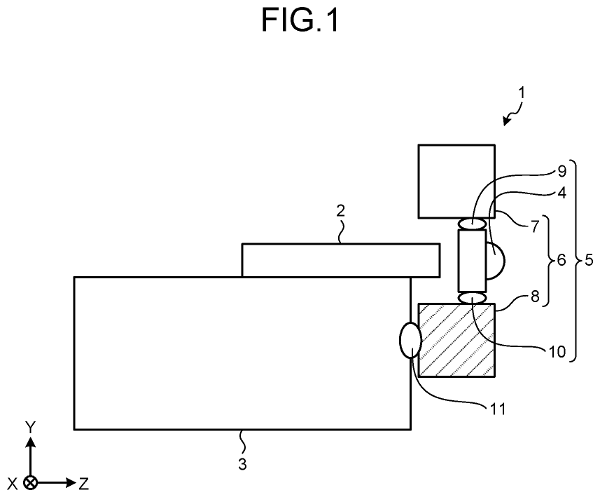

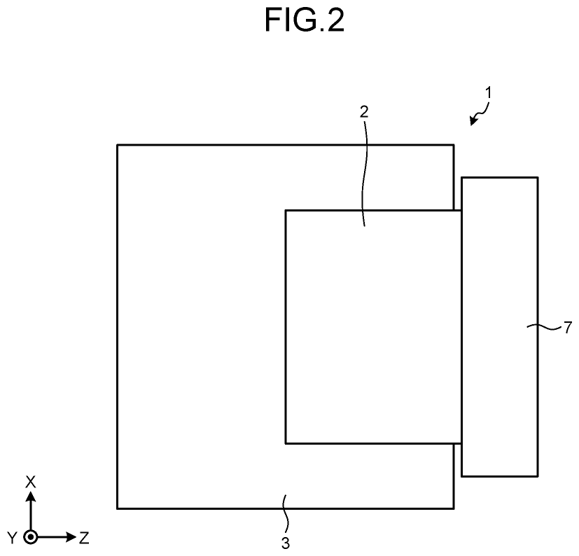

FIG. 1 is a diagram schematically illustrating a side face of an optical module 1 according to a first embodiment. In the drawings of the present application, each of “X”, “Y”, and “Z” indicates an axis, and each of the X axis, the Y axis, and the Z axis is orthogonal to the other two axes. FIG. 1 schematically illustrates the side face of the optical module 1 parallel to a plane including the Y axis and the Z axis. FIG. 2 is a diagram schematically illustrating a plane of the optical module 1 according to the first embodiment. More specifically, FIG. 2 schematically illustrates the plane of the optical module 1 parallel to a plane including the X axis and the Z axis. A positive direction of the Z axis is a direction in which beams of laser light propagate.

The optical module 1 includes a multi-emitter semiconductor laser bar 2 including a plurality of emission points. The multi-emitter semiconductor laser bar 2 is an element that outputs laser light. A semiconductor mainly contributing to the output of the laser light of the multi-emitter semiconductor laser bar 2 is, for example, gallium arsenide. Oscillation output of the multi-emitter semiconductor laser bar 2 is, for example, several hundred watts or more. As described above, the multi-emitter semiconductor laser bar 2 has the plurality of emission points and thus outputs a plurality of beams. Details of the plurality of emission points will be described later.

The optical module 1 further includes a cooling structure 3 on which the multi-emitter semiconductor laser bar 2 is placed and which dissipates heat generated in the multi-emitter semiconductor laser bar 2. For example, a channel for water is formed in the cooling structure 3, and the cooling structure 3 dissipates the heat generated in the multi-emitter semiconductor laser bar 2 as water flows through the channel.

The optical module 1 further includes a lens unit 5 including a collimating lens array 4 for collimating the plurality of beams output from the multi-emitter semiconductor laser bar 2t The collimating lens array 4 is provided in front of the multi-emitter semiconductor laser bar 2 in the direction in which the plurality of beams output from the multi-emitter semiconductor laser bar 2 propagates. A longitudinal direction of the collimating lens array 4 corresponds to the direction of the X axis. For example, the collimating lens array 4 has the shape in a positive direction of the X axis and the shape in a negative direction of the X axis that are symmetrical with respect to the center in the longitudinal direction.

The lens unit 5 further includes a holding member 6 that holds the collimating lens array 4. The holding member 6 includes a first holding member 7 and a second holding member 8 for holding the collimating lens array 4. In the drawings, the second holding member 8 is hatched in order for the first holding ember 7 and the second holding member 8 to be distinguished from each other. The first holding member 7 and the second holding member 8 sandwich the collimating lens array 4 in a direction in which the collimating lens array 4 is curved. A material forming each of the first holding member 7 and the second holding member 8 is preferably the same as a material forming the collimating lens array 4.

The lens unit 5 further includes a first joining member 9 joining the collimating lens array 4 and the first holding member 7, and a second joining member 10 joining the collimating lens array 4 and the second holding member 8. A material forming the first joining member 9 is preferably the same as a material forming the second joining member 10.

The optical module 1 further includes a third joining member 11 joining the cooling structure 3 and the lens unit 5. Specifically, the third joining member 11 joins the first holding member 7 or the second holding member 8 and the cooling structure 3. FIG. 1 illustrates a state in which the third joining member 11 joins the second holding member 8 and the cooling structure 3. The third joining member 11 is preferably formed of an ultraviolet curing resin adhesive. A level of heat resistance of each of the first joining member 9 and the second joining member 10 is preferably higher than a level of heat resistance of the third joining member 11. FIGS. 1 and 2 do not illustrate a power supply mechanism that supplies current to the multi-emitter semiconductor laser bar 2. A line connecting the center of the multi-emitter semiconductor laser bar 2 on a plane parallel to a plane including the X axis and the Y axis (hereinafter referred to as an XY plane in some cases) and the center of the collimating lens array 4 on a plane parallel to the XY plane is parallel to the Z axis.

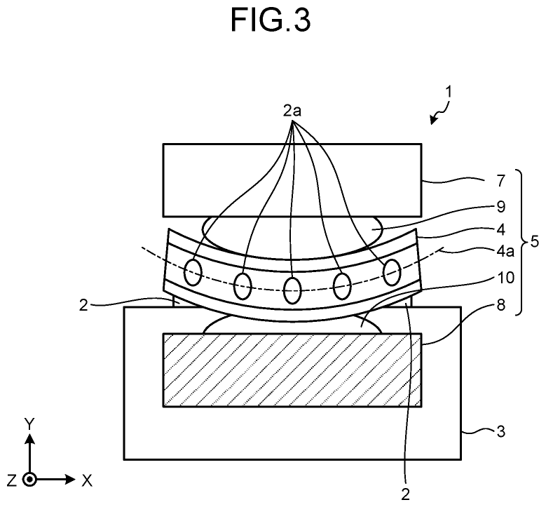

FIG. 3 is a diagram schematically illustrating a front face of the optical module 1 according to the first embodiment. The front face is a face on a side where the multi-emitter semiconductor laser bar 2 outputs the plurality of beams. More specifically, the front face is a plane parallel to the plane including the X axis and the Y axis. As can be seen from FIG. 1, when the front face is viewed in a direction from the positive side of the Z axis to the negative side of the Z axis, a plurality of emission points 2a of the multi-emitter semiconductor laser bar 2 is hidden by the collimating lens array 4. However, FIG. 3 illustrates the plurality of emission points 2a of the multi-emitter semiconductor laser bar 2. The plurality of emission points 2a in FIG. 3 is illustrated to explain that the multi-emitter semiconductor laser bar 2 has the plurality of emission points 2a.

FIG. 3 illustrates an arc 4a indicating the curve of the collimating lens array 4. The arc 4a is indicated by a dash-dot line. The curve of the collimating lens array 4 is the curve of the collimating lens array 4 on a plane that is orthogonal to the direction of propagation of the plurality of beams output from the multi-emitter semiconductor laser bar 2 and includes the collimating lens array 4. As indicated by the arc 4a, the curve of the collimating lens array 4 in FIG. 3 is oriented so as to bulge to the negative side of the Y axis.

In the optical module 1, the curve of the collimating lens array 4 is in the same orientation as a curve of a line connecting the plurality of emission points 2a to each other on a plane that is orthogonal to the direction of propagation of the plurality of beams output from the multi-emitter semiconductor laser bar 2 and includes the plurality of emission points 2a.

Next, a method of manufacturing an optical module according to the first embodiment will be described. First, measurement is performed on the orientation of the curve of the line connecting the plurality of emission points 2a to each other on the plane that is orthogonal to the direction of propagation of the plurality of beams output from the multi-emitter semiconductor laser bar 2 and includes the plurality of emission points 2a. Next, measurement is performed on the orientation of the curve of the collimating lens array 4 on the plane that is orthogonal to the direction of propagation of the beams collimated by the collimating lens array 4 and includes the collimating lens array 4. Next, the first holding member 7 and the second holding member 8 are used to align the measured orientation of the curve of the collimating lens array 4 with the measured orientation of the curve of the line connecting the plurality of emission points 2a.

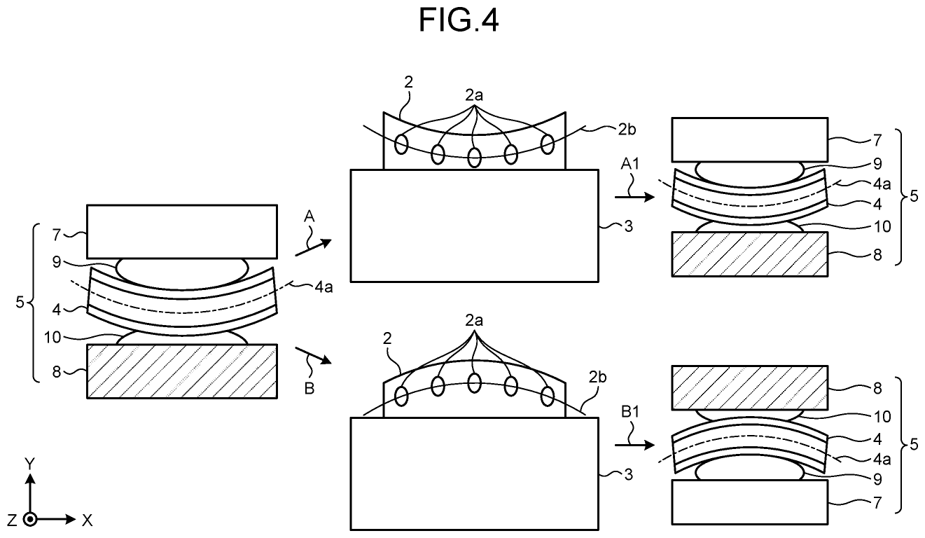

Next, a description will be made of the operation that aligns the orientation of the curve of the collimating lens array 4 with the measured orientation of the curve of the line connecting the plurality of emission points 2a. FIG. 4 is a set of diagrams for explaining the method of manufacturing the optical module 1 according to the first embodiment. As illustrated on the left of arrows A and B in FIG. 4, it is assumed that the curve of the collimating lens array 4 is oriented so as to bulge to the negative side of the Y axis.

As illustrated on the right of arrow A, in a case where the curve of a line 2b connecting the plurality of emission points 2a of the multi-emitter semiconductor laser bar 2 is oriented so as to bulge to the negative side of the Y axis, the lens unit 5 is not rotated about a central axis parallel to the Z axis of the lens unit 5, as illustrated on the right of arrow A1. Then, the third joining member 11 is used to join the lens unit 5 to the cooling structure 3 on which the multi-emitter semiconductor laser bar 2 is placed, Specifically, the third joining member 11 is used to join the second holding member 8 to the cooling structure 3. Accordingly, the optical module 1 is manufactured. Note that the line 2b connecting the plurality of emission points 2a is indicated by a solid line.

As illustrated on the right of arrow B, in a case where the curve of the line 2b connecting the plurality of emission points 2a of the multi-emitter semiconductor laser bar 2 is oriented so as to bulge to the positive side of the Y axis, the first holding member 7 and the second holding member 8 are used to rotate the lens unit 5 halfway about the central axis parallel to the Z axis of the lens unit 5 so that the curve of the collimating lens array 4 is oriented so as to bulge to the positive side of the Y axis, as illustrated on the right of arrow Bl. Then, the third joining member 11 is used to join the lens unit 5 to the cooling structure 3 on which the multi-emitter semiconductor laser bar 2 is placed, Specifically, the third joining member 11 is used to join the first holding member 7 to the cooling structure 3. Accordingly, the optical module 1 is manufactured.

As described above, in the optical module 1 according to the first embodiment, the curve of the collimating lens array 4 is in the same orientation as the curve of the line 2b connecting the plurality of emission points 2a of the multi-emitter semiconductor laser bar 2. This can prevent the plurality of beams output by the multi-emitter semiconductor laser bar 2 from not traveling in straight lines. Therefore, the optical module 1 can prevent the occurrence of a loss of propagation of the laser light that is output therefrom. In other words, the optical module 1 can cause the output laser light to propagate efficiently.

In the first embodiment, the optical module 1 is manufactured by aligning the orientation of the curve of the collimating lens array 4 with the orientation of the curve of the line 2b connecting the plurality of emission points 2a. Therefore, the method of manufacturing an optical module according to the first embodiment can manufacture the optical module 1 that prevents the occurrence of the loss of propagation of the laser light that is output from the optical module 1.

Note that the first holding member 7 and the second holding member 8 may be connected by a member not illustrated.

### Second Embodiment

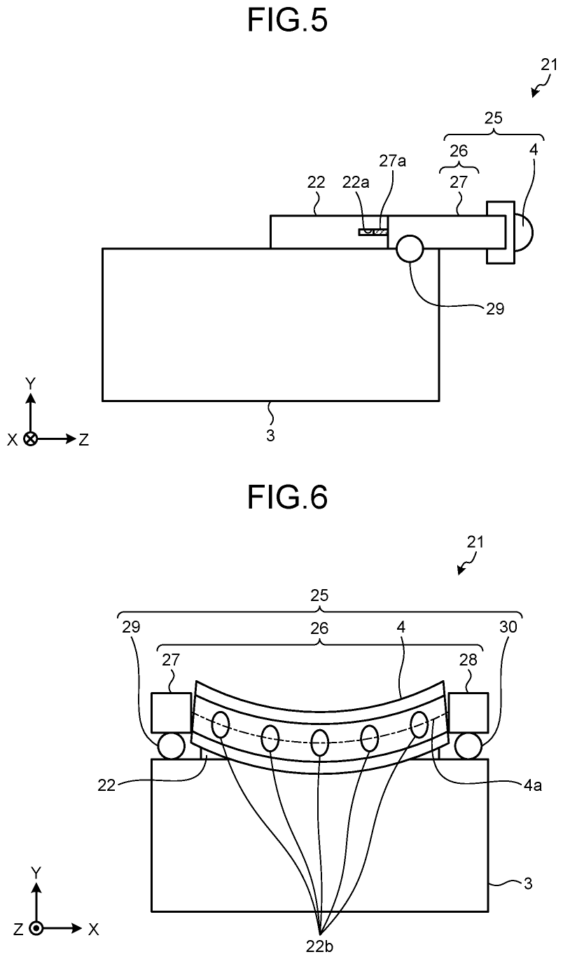

FIG. 5 is a diagram schematically illustrating a side face of an optical module 21 according to a second embodiment. FIG. 5 schematically illustrates the side face of the optical module 21 parallel to a plane including the Y axis and the Z axis. The optical module 21 includes a multi-emitter semiconductor laser bar 22 including a plurality of emission points. The multi-emitter semiconductor laser bar 22 is an element that outputs laser light. A semiconductor mainly contributing to the output of the laser light of the multi-emitter semiconductor laser bar 22 is, for example, gallium arsenide. The oscillation output of the multi-emitter semiconductor laser bar 22 is, for example, several hundred watts or more. As described above, the multi-emitter semiconductor laser bar 22 has the plurality of emission points and thus outputs a plurality of beams. Details of the plurality of emission points will be described later.

The optical module 21 further includes the cooling structure 3 on which the multi-emitter semiconductor laser bar 22 is placed and which dissipates heat generated in the multi-emitter semiconductor laser bar 22. For example, a channel for water is formed in the cooling structure 3, and the cooling structure 3 dissipates the heat generated in the multi-emitter semiconductor laser bar 22 as water flows through the channel.

The optical module 21 further includes a lens unit 25 including the collimating lens array 4 for collimating the plurality of beams output from the multi-emitter semiconductor laser bar 22. The collimating lens array 4 is provided in front of the multi-emitter semiconductor laser bar 22 in a direction in which the plurality of beams output from the multi-emitter semiconductor laser bar 22 propagates. The longitudinal direction of the collimating lens array 4 corresponds to the direction of the X axis. For example, the collimating lens array 4 has the shape in the positive direction of the X axis and the shape in the negative direction of the X axis that are symmetrical with respect to the center in the longitudinal direction.

The lens unit 25 further includes a holding member 26 that holds the collimating lens array 4. The holding member 26 includes a third holding member 27 and a fourth holding member 28 for holding the collimating lens array 4. In FIG. 5, a part of the third holding member 27 is hatched. The fourth holding member 28 is not illustrated in FIG. 5 but is illustrated in FIG. 6. As will be described later with reference to FIG. 6, the third holding member 27 and the fourth holding member 28 sandwich the collimating lens array 4 in a direction orthogonal to the orientation of the curve of the collimating lens array 4, and allow passage of the plurality of beams collimated by the collimating lens array 4.

The third holding member 27 and the fourth holding member 28 each include a protrusion protruding in a direction from the collimating lens array 4 toward the multi-emitter semiconductor laser bar 22 in a direction parallel to the direction of propagation of the plurality of beams output from the multi-emitter semiconductor laser bar 22. The part of the third holding member 27 hatched in FIG. 5 is a protrusion 27a included in the third holding member 27. The protrusion included in the fourth holding member 28 is the same as the protrusion 27a and is not illustrated.

The multi-emitter semiconductor laser bar 22 includes a first recess 22a into which one of the protrusion 27a of the third holding member 27 and the protrusion of the fourth holding member 26 is fitted, and a second recess into which the other one of the protrusion 27a of the third holding member 27 and the protrusion of the fourth holding member 26 is fitted. FIG. 5 illustrates a state in which the protrusion 27a of the third holding member 27 is fitted into the first recess 22a. The second recess is the same as the first recess 22a and is not illustrated.

Although none of the protrusion 27a of the third holding member 27, the protrusion of the fourth holding member 28, the first recess 22a, and the second recess is formed on the side face of the optical module 21, for convenience of description, FIG. 5 illustrates the protrusion 27a of the third holding member 27 and the first recess 22a. In the optical module 21 of FIG. 5, the protrusion 27a of the third holding member 27 is fitted into the first recess 22a, and the protrusion of the fourth holding member 28 is fitted into the second recess. A material forming each of the third holding member 27 and the fourth holding member 28 is preferably the same as the material forming the collimating lens array 4.

Moreover, the optical module 21 need not include the protrusion 27a and the first recess 22a. In this case, a jig or the like is used from the outside at a specified relative position to place the third holding member 27 on the cooling structure 3 and then fix the third holding member 27 to the cooling structure 3. Also, the optical module 21 need not include the protrusion of the fourth holding member 28 and the second recess. In this case, a jig or the like is used from the outside at a specified relative position to place the fourth holding member 28 on the cooling structure 3 and then fix the fourth holding member 28 to the cooling structure 3.

The optical module 21 further includes a fourth joining member 29 joining the cooling structure 3 and the third holding member 27 of the lens unit 25, and a fifth joining member 30 joining the cooling structure 3 and the fourth holding member 28 of the lens unit 25. The fifth joining member 30 is not illustrated in FIG. 5 but is illustrated in FIG. 6. Each of the fourth joining member 29 and the fifth joining member 30 is preferably formed of an ultraviolet curing resin adhesive. FIG. 5 does not illustrate a power supply mechanism that supplies current to the multi-emitter semiconductor laser bar 22.

FIG. 6 is a diagram schematically illustrating a front face of the optical module 21 according to the second embodiment. The front face is a face on a side where the multi-emitter semiconductor laser bar 22 outputs the plurality of beams. More specifically, the front face is the plane parallel to the plane including the X axis and the Y axis. As can be seen from FIG. 5, when the front face is viewed in a direction from the positive side of the Z axis to the negative side of the Z axis, a plurality of emission points 22b of the multi-emitter semiconductor laser bar 22 is hidden by the collimating lens array 4. However, FIG. 6 illustrates the plurality of emission points 22b of the multi-emitter semiconductor laser bar 22. The plurality of emission points 22b in FIG. 6 is illustrated to explain that the multi-emitter semiconductor laser bar 22 has the plurality of emission points 22b.

FIG. 6 illustrates the arc 4a indicating the curve of the collimating lens array 4. The arc 4a is indicated by a dash-dot line. The curve of the collimating lens array 4 is the curve of the collimating lens array 4 on a plane that is orthogonal to the direction of propagation of the plurality of beams output from the multi-emitter semiconductor laser bar 22 and includes the collimating lens array 4. As indicated by the arc 4a, the curve of the collimating lens array 4 in FIG. 6 is oriented so as to bulge to the negative side of the Y axis:

In the optical module 21, the curve of the collimating lens array 4 is in the same orientation as a curve of a line connecting the plurality of emission points 22b on a plane that is orthogonal to the direction of propagation of the plurality of beams output from the multi-emitter semiconductor laser bar 22 and includes the plurality of emission points 22b.

Next, a method of manufacturing an optical module according to the second embodiment will be described. First, measurement is performed on the orientation of the curve of the line connecting the plurality of emission points 22b on the plane that is orthogonal to the direction of propagation of the plurality of beams output from the multi-emitter semiconductor laser bar 22 and includes the plurality of emission points 22b. Next, measurement is performed on the orientation of the curve of the collimating lens array 4 on the plane that is orthogonal to the direction of propagation of the beams collimated by the collimating lens array 4 and includes the collimating lens array 4, Next, the third holding member 27 and the fourth holding member 22 are used to align the measured orientation of the curve of the collimating lens array 4 with the measured orientation of the curve of the line connecting the plurality of emission points 22b.

Next, in the state where the orientation of the curve of the collimating lens array 4 is aligned with the orientation of the curve of the line connecting the plurality of emission points 22b, in the direction of propagation of the plurality of beams output from the multi-emitter semiconductor laser bar 22, one of the protrusion 27a of the third holding member 27 and the protrusion of the fourth holding member 28 is fitted into the first recess 22a, and the other one of the protrusion 27a of the third holding member 27 and the protrusion of the fourth holding member 28 is fitted into the second recess. Accordingly, the optical module 21 is manufactured.

Note that in a case where the optical module 21 does not include the protrusion 27a and the first recess 22a, a jig or the like is used from the outside at a specified relative position to place the third holding member 27 on the cooling structure 3 and then fix the third holding member 27 to the cooling structure 3. Also, in a case where the optical module 21 does not include the protrusion of the fourth holding member 28 and the second recess, a jig or the like is used from the outside at a specified relative position to place the fourth holding member 28 on the cooling structure 3 and then fix the fourth holding member 28 to the cooling structure 3.

As described above, in the optical module 21 according to the second embodiment, the curve of the collimating lens array 4 is in the same orientation as the curve of the line connecting the plurality of emission points 22b of the multi-emitter semiconductor laser bar 22. This can prevent the plurality of beams output by the multi-emitter semiconductor laser bar 22 from not traveling in straight lines. Therefore, the optical module 21 can prevent the occurrence of a loss of propagation of the laser light that is output therefrom. In other words, the optical nodule 21 can cause the output laser light to propagate efficiently.

In the second embodiment, the optical module 21 is manufactured by aligning the orientation of the curve of the collimating lens array 4 with the orientation of the curve of the line connecting the plurality of emission points 22b, Therefore, the method of manufacturing an optical module according to the second embodiment can manufacture the optical module 21 that prevents the occurrence of the loss of propagation of the laser light that is output therefrom.

### Third Embodiment

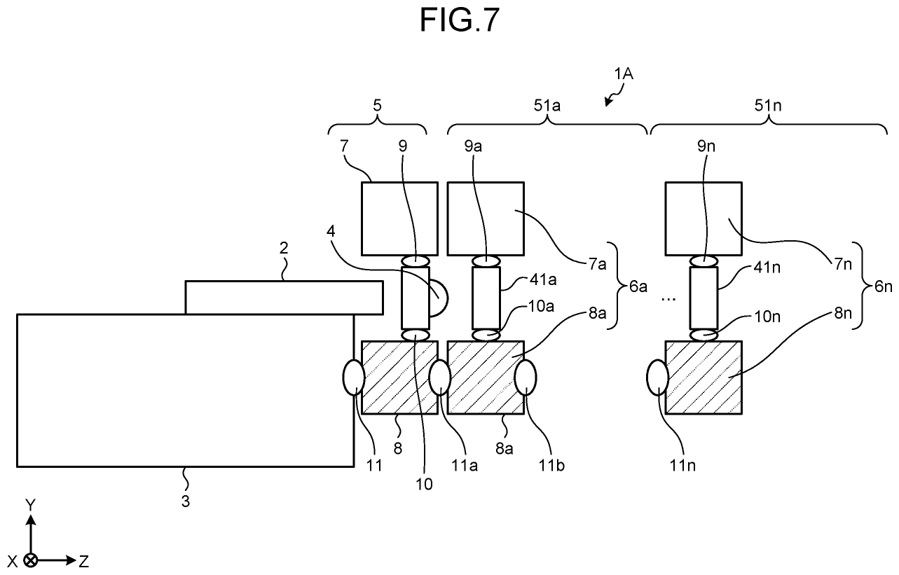

FIG. 7 is a diagram schematically illustrating a Bide face of an optical module 1A according to a third embodiment. FIG. 7 schematically illustrates the side face of the optical module 1A parallel to a plane including the Y axis and the Z axis. FIG. 7 does not illustrate a power supply mechanism that supplies current to the multi-emitter semiconductor laser bar 2.

The optical module 1A includes all the components included in the optical module 1 according to the first embodiment. The optical module 1A includes components not included in the optical module 1. The third embodiment mainly describes differences from the first embodiment, Note that FIG. 7 omits the illustration of reference numeral “6” of the holding member 6.

The optical module 1A further includes element units 51a, . . . , and 51n including respective optical elements 41a, . . . , and 41n not included in the optical module 1. The optical elements 41a, . . . , and 41n are provided in front of the collimating lens array 4 in a direction in which the plurality of beams output from the multi-emitter semiconductor laser bar 2 propagates. For example, each of the optical elements 41a, . . . , and 41n has a function different from that of the other optical elements. Each of the optical elements 41a, . . . , and 41n is, for example, a microlens array, a beam transfer system, or a prism. The longitudinal direction of the optical elements 41a, . . . , and 41n corresponds to the direction of the X axis. For example, the optical elements 41a, . . . , and 41n each have the shape in the positive direction of the X axis and the shape in the negative direction of the X axis that are symmetrical with respect to the center in the longitudinal direction.

In the optical module 1A, the element units 51a, . . . , and 51n are disposed in the order of the element units 1a, . . . , and 51n from the negative side to the positive side of the Z axis in the direction parallel to the Z axis.

The element units 51a, . . . , and 51n further include respective holding members 6a, . . . , and 6n that hold the respective optical elements 41a, . . . , and 41n. The holding members 6a, . . . , and 6n include respective first holding members 7a, . . . , and 7n and second holding members 8a, . . . , and 8n for holding the respective optical elements 41a, . . . , and 41n.

The element units 51a, . . . , and 51n further include respective first joining members 9a, . . . , and 9n joining the respective optical elements 41a, . . . , and 41n and first holding members 7a, . . . , and 7n, and respective second joining members 10a, . . . , and 10n joining the respective optical elements 41a, . . . , and 41n and second holding members 8a, . . . , and 8n. A material forming the first joining members 9a, . . . , and 9n is preferably the same as a material forming the second joining members 10a, and 10n.

The element units 1a, . . . , and 51n further include respective third joining members 11a, . . . , and 11n. The third joining member 11a joins the second holding member Ba and the second holding member S. The third joining members 11b, . . . , and 11n each join the second holding members adjacent to each other. For example, the third joining member 1b joins the second holding members 8a and 8b, and the third joining member 11n joins the second holding members 8(n−1) and Sn.

Note that the third joining member 11a may join the first holding member 7a and the first holding member 7. Likewise, the third joining members 11b, . . . , and 11n may each join the first holding members adjacent to each other. In this case, for example, the third joining member 11b joins the first holding members 7a and 7b, and the third joining member 11n joins the first holding members 7(n−1) and 7n. The third joining members 11, . . . , and 11n each join at least either the adjacent second holding members or the adjacent first holding members.

A line connecting the centers of the first holding members 7, 7a, . . . , and 7n on a plane parallel to the XY plane, a line connecting the centers of the second holding members B, Ba, . . . , and Sn on a plane parallel to the XY plane, and a line connecting the centers of the optical elements 41a, . . . , and 41n on a plane parallel to the XY plane are all parallel to the Z axis.

Also, a line connecting the centers of the first joining members 9a, . . . , and 9n on a plane parallel to the XY plane, a line connecting the centers of the second joining members 10a, . . . , and 10n a plane parallel to the XY plane, and a line connecting the centers of the third joining members 11a, . . . , and 11n on a plane parallel to the XY plane are all parallel to the Z axis. Moreover, the center of the collimating lens array 4 on the XY plane is located on the line connecting the centers of the optical elements 41a, . . . , and 41n on the plane parallel to the XY plane.

As described above, the optical module 1A includes one or a plurality of the element units. Each of the element units includes one piece of the optical element, one piece of the first holding member, one piece of the second holding member, one piece of the first joining member, one piece of the second joining member, and one piece of the third joining member. Note that since the element units 51a, . . . , and 51n have similar structures, the structure of the element unit 51n will be described below.

The first holding member 7n and the second holding member Sn sandwich the optical element 41n in a direction in which the optical element 41n is curved. That is, the first holding member 7n and the second holding member Sn sandwich the optical element 41n in a direction parallel to the Y axis. Specifically, in the direction parallel to the Y axis from the negative side to the positive side of the Y axis, the second holding member Sn, the optical element 41n, and the first holding member 7n are disposed in the order of the second holding member Sn, the optical element 41n, and the first holding member 7n.

A material forming each of the first holding member 7n and the second holding member Sn is preferably the same as a material forming the optical element 41n. The third joining member 11n is preferably formed of an adhesive or an ultraviolet curing material. The level of heat resistance of each of the first joining member 9n and the second joining member 10n is preferably higher than the level of heat resistance of the third joining member 11n. It is preferable that the farther each of the first joining members 9a, . . . , and 9n and the second joining members 10a, . . . , and 10n is from the cooling structure 3, the higher the level of heat resistance thereof becomes.

In a case where the optical module 1A according to the third embodiment is viewed from the front, as compared with the case where the optical module 1 according to the first embodiment illustrated in FIG. 3 is viewed from the front, the optical element 41n is visible instead of the collimating lens array 4, and the first holding member 7n is visible instead of the first holding member 7. Likewise, the second holding member Sn is visible instead of the second holding member 8, the first joining member 9n is visible instead of the first joining member 9, and the second joining member 10n is visible instead of the second joining member 10.

In the third embodiment, for each of the optical elements 41a, . . . , and 41n, a curve on a plane orthogonal to the direction of propagation of the plurality of beams output from the multi-emitter semiconductor laser bar 2 is in the same orientation as the curve of the line connecting the plurality of emission points 2a.

FIG. B is a flowchart illustrating an example of a procedure for a method of manufacturing the optical module 1A according to the third embodiment. When the optical module 1A is manufactured, the orientation of the curve of the multi-emitter semiconductor laser bar 2 in the direction of the Y axis is measured (step S). That is, in step S1, the orientation of the curve of the line connecting the plurality of emission points 2a in the direction of the Y axis is measured. Specifically, measurement is performed on the orientation of the curve of the line connecting the plurality of emission points 2a on the plane that is orthogonal to the direction of propagation of the plurality of beams output from the multi-emitter semiconductor laser bar 2 and includes the plurality of emission points 2a.

Next, the orientation of the curve of the collimating lens array 4 in the direction of the Y axis is measured (step S2). Specifically, measurement is performed on the orientation of the curve of the collimating lens array 4 on the plane that is orthogonal to the direction of propagation of the beams collimated by the collimating lens array 4 and includes the collimating lens array 4.

Next, the orientation of the curve of each of the optical elements 41a, . . . , and 41n in the direction of the Y axis is measured (step 33). Specifically, similarly to the collimating lens array 4, for each of the optical elements 41a, . . . , and 41n, the orientation of the curve on the plane orthogonal to the direction of propagation of the passing beams is measured.

The first holding member 7 is joined to the collimating lens array 4 by the first joining member 9, and the second holding member 8 is joined to the collimating lens array 4 by the second joining member 10. Accordingly, the lens unit 5 is thus formed. Note that the orientation of the curve of the collimating lens array 4 may be measured after or before the lens unit 5 is formed.

Also, the first holding members 7a, . . . , and 7n are joined to the respective optical elements 41a, . . . , and 41n by the respective first joining members 9a, . . . , and 9n, and the second holding members 8a, . . . , and 8n are joined to the respective optical elements 41a, . . . , and 41n by the respective second joining members 10a, . . . , and 10n. Accordingly, the element units 51a, . . . , and 51n are thus formed Note that the orientations of the curves of the optical elements 41a, . . . , and 41n may be measured after or before the element units 51a, . . . , and 51n are formed.

Next, the orientation of the curve of the collimating lens array 4 is aligned with the orientation of the curve of the multi-emitter semiconductor laser bar 2 (step S4) Specifically, the measured orientation of the curve of the collimating lens array 4 is aligned with the measured orientation of the curve of the line connecting the plurality of emission points 2a, That is, the lens unit 5 is disposed in the vicinity of the cooling structure 3 to which the multi-emitter semiconductor laser bar 2 is joined such that the orientation of the curve of the collimating lens array 4 is aligned with the orientation of the curve of the multi-emitter semiconductor laser bar 2.

Next, the lens unit 5 is joined to the cooling structure 3 (step 65) Note that the lens unit 5 may be joined to the cooling structure 3 first, or the multi-emitter semiconductor laser bar 2 may be joined to the cooling structure 3 first. That is, the multi-emitter semiconductor laser bar 2 may be joined to the cooling structure 3 after the lens unit 5 is joined to the cooling structure 3, or the lens unit 5 may be joined to the cooling structure 3 after the multi-emitter semiconductor laser bar 2 is joined to the cooling structure 3.

Next, the orientations of the curves of the optical elements 41a, . . . , and 41n are aligned with the orientation of the curve of the multi-emitter semiconductor laser bar 2 (step S6). Specifically, the measured orientations of the curves of the optical elements 41a, . . . , and 41n are aligned with the measured orientation of the curve of the line connecting the plurality of emission points 2a. That is, the element units 51a, . . . , and Sin are disposed in the vicinity of the lens unit 5 such that the orientations of the curves of the optical elements 41a, . . . , and 41n are the same as the orientation of the curve of the multi-emitter semiconductor laser bar 2.

Next, the element units 51a, . . . , and 51n are joined to the lens unit 5 (step S7) Note that the element units 51a, . . . , and 51n may be joined to the lens unit 5 first, or the cooling structure 3 may be joined to the lens unit 5 first. That is, the cooling structure 3 may be joined to the lens unit 5 after the element units 51a, . . . , and 51n are joined to the lens unit 5, or the element units 51a, . . . , and 51n may be joined to the lens unit 5 after the cooling structure 3 is joined to the lens unit 5.

Note that steps S1, S2, and S3 may be executed in any order. Also, the multi-emitter semiconductor laser bar 2, the cooling structure 3, the lens unit 5, and the element units 51a, . . . , and 51n may be fixed in any order.

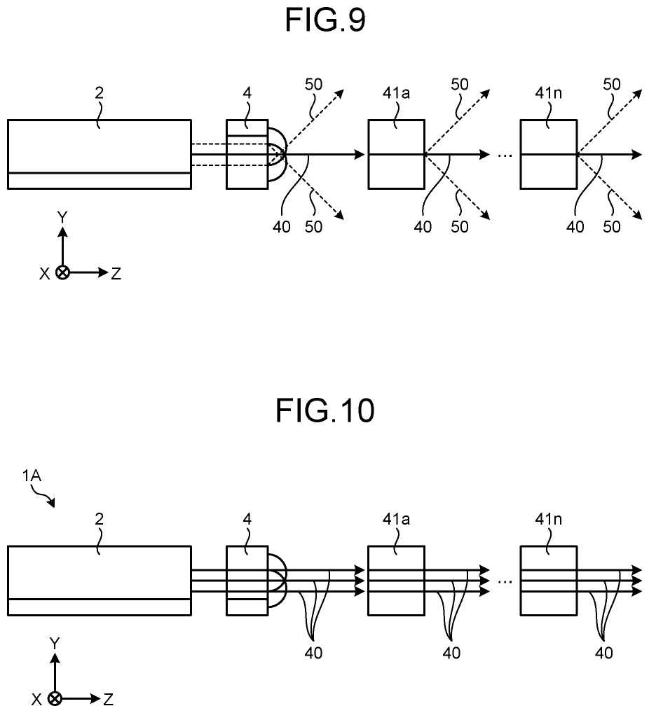

FIG. 9 is a first diagram for explaining an effect obtained by the optical module 1A according to the third embodiment. In FIG. 9, the orientation of the curve of the collimating lens array 4 is different from the orientation of the curve of the line connecting the plurality of emission points 2a of the multi-emitter semiconductor laser bar 2. Moreover, as for the optical elements 41a, . . . , and 41n, the orientation of the curve of the optical element 41a is different from that of the collimating lens array 4, and the orientation of the curve of each of the optical elements 41b, . . . , and 41n is different from the orientation of the curve of the preceding optical element. That is, in the case of the optical elements 41b, . . . , and 41n, the orientation of the curve of an x-th optical element counted from the collimating lens array 4 is different from the orientation of the curve of an (x−1)-th optical element counted from the collimating lens array 4.

In the situation illustrated in FIG. 9, the plurality of beams output from the multi-emitter semiconductor laser bar 2 includes a straight ahead beam 40 and also a non-straight ahead beam 50. The non-straight ahead beam 50 occurs in each of the collimating lens array 4 and the optical elements 41a, . . . , and 41n. The occurrence of the non-straight ahead beam 50 means that the laser light output from the multi-emitter semiconductor laser bar 2 does not propagate efficiently.

FIG. 10 is a second diagram for explaining an effect obtained by the optical module 1A according to the third embodiment. In FIG. 10, the orientation of the curve of the collimating lens array 4 is aligned with the orientation of the curve of the line connecting the plurality of emission points 2a of the multi-emitter semiconductor laser bar 2. The orientation of the curve of each of the optical elements 41a, . . . , and 41n is also aligned with the orientation of the curve of the line connecting the plurality of emission points 2a.

That is, FIG. 10 illustrates a state of propagation of the plurality of beams in the optical module 1A according to the third embodiment. As described above, the orientation of the curve of the collimating lens array 4 and the orientation of the curve of each of the optical elements 41a, . . . , and 41n are aligned with the orientation of the curve of the line connecting the plurality of emission points 2a, whereby the occurrence of the non-straight ahead beam 50 is prevented, and a relatively large number of the plurality of beams output from the multi-emitter semiconductor laser bar 2 become the straight ahead beams 40. Therefore, the optical module 1A can prevent the occurrence of a loss of propagation of the laser light that is output.

As described above, in the optical module 1A according to the third embodiment, the curve of the collimating lens array 4 and the curve of each of the optical elements 41a, . . . , and 41n are in the same orientation as the curve of the line connecting the plurality of emission points 2a of the multi-emitter semiconductor laser bar 2. This can prevent the plurality of beams output by the multi-emitter semiconductor laser bar 2 from not traveling in straight lines. Therefore, the optical module 1A can prevent the occurrence of a loss of propagation of the laser light that is output therefrom. In other words, the optical module 1A can cause the output laser light to propagate efficiently.

In the third embodiment, the optical module 1A is manufactured by aligning the orientation of the curve of the collimating lens array 4 and the orientation of the curve of each of the optical elements 41a, . . . , and 41n with the orientation of the curve of the line connecting the plurality of emission points 2a. Therefore, the method of manufacturing an optical module according to the third embodiment can manufacture the optical module 1A that prevents the occurrence of the loss of propagation of the laser light that is output therefrom.

### Fourth Embodiment

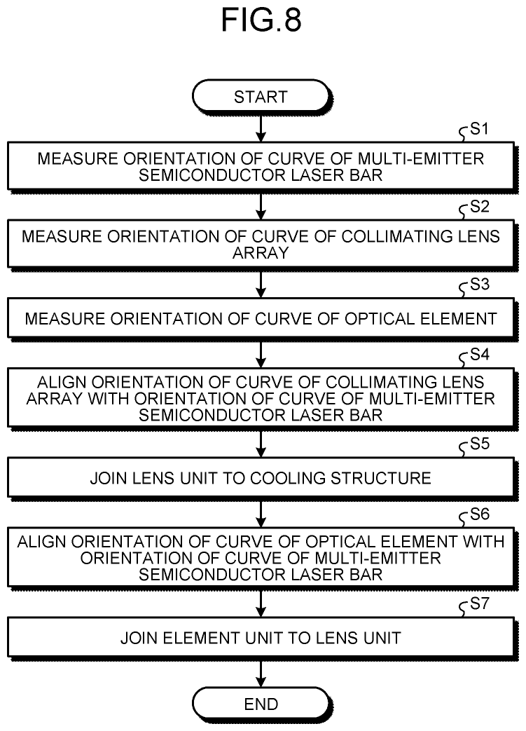

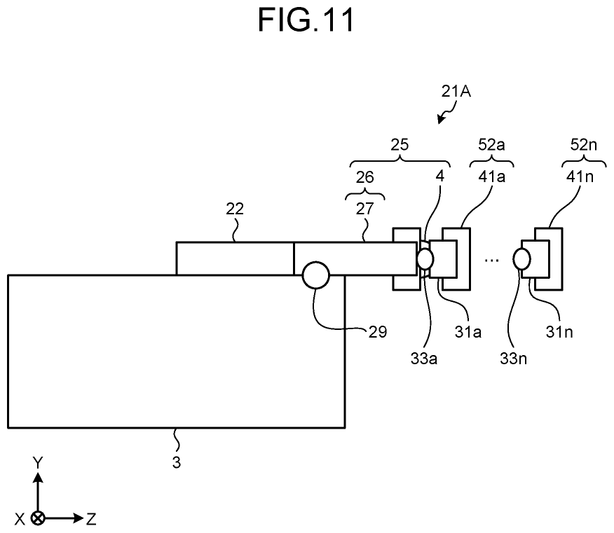

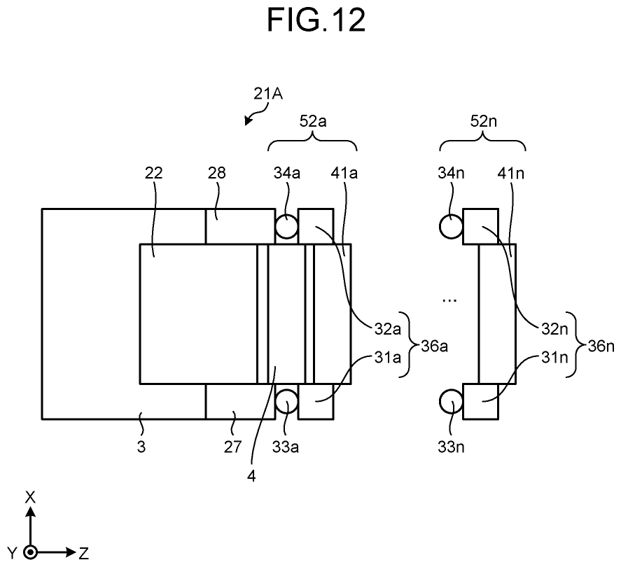

FIG. 11 is a diagram schematically illustrating a side face of an optical module 21A according to a fourth embodiment a FIG. 11 schematically illustrates the side face of the optical module 21A parallel to a plane including the Y axis and the Z axis. FIG. 12 is a diagram schematically illustrating a plane of the optical module 21A according to the fourth embodiment. FIG. 12 schematically illustrates the plane of the optical module 21A parallel to a plane including the X axis and the Z axis. FIGS. 11 and 12 do not illustrate a power supply mechanism that supplies current to the multi-emitter semiconductor laser bar 22. Note that, also in the fourth embodiment, the optical module 21A is manufactured by a procedure similar to that of the third embodiment described with reference to FIG. 8.

The optical module 21A includes all the components included in the optical module 21 according to the second embodiment. The optical module 21A includes components not included in the optical module 21. The fourth embodiment mainly describes differences from the second embodiment.

Note that FIG. 12 omits the illustration of reference numeral “26” of the holding member 26 and reference numeral “5” of the lens unit 5. Moreover, the fourth embodiment describes a case where the optical module 21A does not include the protrusion 27a and the first recess 22a, but the optical module 21A may include the protrusion 27a and the first recess 22a.

The optical module 21A further includes element units 52a, . . . , and 52n including the respective optical elements 41a, . . . , and 41n not included in the optical module 21, The optical elements 41a, . . . , and 41n are provided in front of the collimating lens array 4 in a direction in which the plurality of beams output from the multi-emitter semiconductor laser bar 2 propagates. The optical elements 41a, . . . , and 41n of the optical module 21A are disposed at positions similar to those of the optical elements 41a, . . . , and 41n of the optical module 1A, and have functions similar to those thereof.

In the optical module 21A, the element units 52a, . . . , and 52n are disposed in the order of the element units 52a, . . . , and 52n from the negative side to the positive side of the Z axis in the direction parallel to the Z axis.

The element units 52a, . . . , and 52n further include respective holding members 36a, . . . , and 36n that hold the respective optical elements 41a, . . . , and 41n. The holding members 36a, . . . , and 36n include respective fifth holding members 31a, . . . , and 31n and sixth holding members 32a, . . . , and 32n for holding the respective optical elements 41a, . . . , and 41n. The sixth holding members 32a, . . . , and 32n are not illustrated in FIG. 11 but are illustrated in FIG. 12.

The element units 52a, and 52n further include respective sixth joining members 33a, . . . , and 33n and seventh joining members 34a, . . . , and 34n. A material forming the sixth joining members 33a, . . . , and 33n is preferably the same as a material forming the seventh joining members 34a, . . . , and 34n.

The sixth joining member 33a joins the third holding member 27 and the fifth holding member 31a. The seventh joining member 34a joins the fourth holding member 26 and the sixth holding member 32a.

The sixth joining members 33b, . . . , and 33n each join the fifth holding members adjacent to each other. For example, the sixth joining member 33b joins the fifth holding members 31a and 31b, and the sixth joining member 33n joins the fifth holding members 31(n−1) and 31n.

The seventh joining members 34b, . . . , and 34n each join the sixth holding members adjacent to each other. For example, the seventh joining member 34b joins the sixth holding members 32a and 32b, and the seventh joining member 34n joins the sixth holding members 32(n−1) and 32n.

A line connecting the centers of the fifth holding members 31a, . . . , and 31n on a plane parallel to the XY plane, a line connecting the centers of the sixth holding members 32a, . . . , and 32n on a plane parallel to the XY plane, and a line connecting the centers of the optical elements 41a, . . . , and 41n on a plane parallel to the XY plane are all parallel to the Z axis.

Also, a line connecting the centers of the sixth joining members 33a, . . . , and 33n on a plane parallel to the XY plane and a line connecting the centers of the seventh joining members 34a, . . . , and 34n on a plane parallel to the XY plane are both parallel to the Z axis. Moreover, the center of the collimating lens array 4 on a plane parallel to the XY plane is located on the line connecting the centers of the optical elements 41a, . . . , and 41n on the plane parallel to the XY plane.

As described above, the optical module 21A includes one or a plurality of the element units. Each of the element units includes one piece of the optical element, one piece of the fifth holding member, one piece of the sixth holding member, one piece of the sixth joining member, and one piece of the seventh joining member. Note that since the element units 52a, . . . , and 52n have similar structures, the structure of the element unit 52n will be described below.

The fifth holding member 31n and the sixth holding member 32n sandwich the optical element 41n in a direction orthogonal to the orientation of the curve of the optical element 41n. That is, the fifth holding member 31n and the sixth holding member 32n sandwich the optical element 41n in a direction parallel to the X axis. Specifically, in the direction parallel to the X axis from the negative side to the positive side of the X axis, the fifth holding member 31n, the optical element 41n, and the sixth holding member 32n are disposed in the order of the fifth holding member 31n, the optical element 41n, and the sixth holding member 32n.

A material forming each of the fifth holding member 31n and the sixth holding member 32n is preferably the same as the material forming the optical element 41n. It is preferable that the farther each of the sixth joining members 33b, . . . , and 33n and the seventh joining members 3b, . . . , and 34n are from the cooling structure 3, the higher the level of heat resistance thereof becomes.

In a case where the optical module 21A according to the fourth embodiment is viewed from the front, as compared with the case where the optical module 21 according to the second embodiment illustrated in FIG. 6 is viewed from the front, the optical element 41n is visible instead of the collimating lens array 4. Likewise, the fifth holding member 31n is visible instead of the third holding member 27, and the sixth holding member 32n is visible instead of the fourth holding member 28.

In the fourth embodiment, for each of the optical elements 41a, . . . , and 41n, a curve on a plane orthogonal to the direction of propagation of the plurality of beams output from the multi-emitter semiconductor laser bar 2 is in the same orientation as the curve of the line connecting the plurality of emission points 2a.

As described above, in the optical module 21A according to the fourth embodiment, the curve of the collimating lens array 4 and the curve of each of the optical elements 41a, . . . , and 41n are in the same orientation as the curve of the line connecting the plurality of emission points 2a of the multi-emitter semiconductor laser bar 2. This can prevent the plurality of beams output by the multi-emitter semiconductor laser bar 2 from not traveling in straight lines. Therefore, the optical nodule 21A can prevent the occurrence of a loss of propagation of the laser light that is output therefrom. In other words, the optical module 21A can cause the output laser light to propagate efficiently.

In the fourth embodiment, the optical module 21A is manufactured by aligning the orientation of the curve of the collimating lens array 4 and the orientation of the curve of each of the optical elements 41a, . . . , and 41n with the orientation of the curve of the line connecting the plurality of emission points 2a. Therefore, the method of manufacturing an optical module according to the fourth embodiment can manufacture the optical module 21A that prevents the occurrence of the loss of propagation of the laser light that is output therefrom.

The configurations illustrated in the above embodiments each merely illustrate an example so that another known technique can be combined, the embodiments can be combined together, or the configurations can be partially omitted or modified without departing from the scope of the present disclosure.

### REFERENCE SIGNS LIST

1, 1A, 21, 21A optical nodule; 2, 22 multi-emitter semiconductor laser bar; 2a, 22b emission point; 2b line connecting a plurality of emission points; 3 cooling structure; 4 collimating lens array; 5, 25 lens unit; 6, 6a, . . . , 6n, 26, 36a, . . . , 36n holding member; 7, 7a, . . . , 7n first holding member; 8, 8a, . . . , 8n second holding member; 9, 9a, . . . , 9n first joining member; 10, 10a, . . . , 10n second joining member; 11, 11a, . . . , 11n third joining member; 22a first recess, 27 third holding member; 27a protrusion; 28 fourth holding member; 29 fourth joining member; 30 fifth joining member; 31a, . . . , 31n fifth holding member; 32a, . . . , 32n sixth holding member; 33a, . . . , 33n sixth joining member; 34a, . . . , 34n seventh joining member; 40 straight ahead beam; 41a, . . . , 41n optical element; 50 non-straight ahead beam; 51a, . . . , 51n, 52a, . . . , 52n element unit.

1. An optical module comprising:
a multi-emitter semiconductor laser bar including a plurality of emission points;
a lens unit including a collimating lens array to collimate a plurality of beams output from the multi-emitter semiconductor laser bar; and
one or a plurality of element units including an optical element disposed in front of the lens unit in a direction of propagation of the plurality of beams, wherein
each of the element units further includes a plurality of holders to hold the optical element,
an orientation of a curve of the collimating lens array on a plane that is orthogonal to the direction of propagation and includes the collimating lens array is aligned with an orientation of a curve of a line connecting the plurality of emission points on a plane that is orthogonal to the direction of propagation and includes the plurality of emission points,
an orientation of a curve of each of the optical elements on a plane that is orthogonal to the direction of propagation and includes the optical elements is aligned with the orientation of the curve of the line connecting the plurality of emission points, and
each of the holders includes a first holder and a second holder to hold the optical element by sandwiching the optical element in a direction in which the optical elements are curved,
each of the holders is joined in the direction of propagation by a joining material.

2. (canceled)

3. The optical module according to claim 1, wherein
each of the holders includes a third holder and a fourth holder to hold the optical element by sandwiching the optical element in a direction orthogonal to the orientation of the curve of the optical elements and the direction of propagation.

4. A method of manufacturing an optical module that includes a multi-emitter semiconductor laser bar including a plurality of emission points, a collimating lens array to collimate a plurality of beams output from the multi-emitter semiconductor laser bar, and one or a plurality of optical elements disposed in front of the collimating lens array in a direction of propagation of the plurality of beams, wherein
each of the optical elements is held by a holder, and
the method includes:
measuring an orientation of a curve of a line connecting the plurality of emission points on a plane that is orthogonal to the direction of propagation and includes the plurality of emission points;
measuring an orientation of a curve of the collimating lens array on a plane that is orthogonal to the direction of propagation and includes the collimating lens array;
measuring an orientation of a curve of the optical elements on a plane that is orthogonal to the direction of propagation and includes the optical elements;
aligning the measured orientation of the curve of the collimating lens array with the measured orientation of the curve of the line connecting the plurality of emission points; and
aligning the measured orientation of the curve of the optical elements with the measured orientation of the curve of the line connecting the plurality of emission points, and joining each of the holder in the direction of propagation by a joining material,
wherein the holder includes a first holder and a second holder to hold the optical element by sandwiching the optical element in a direction in which the optical element is curved.

5. The method of manufacturing an optical module according to claim 4, wherein
the aligning the measured orientation of the curve of the collimating lens array with the measured orientation of the curve of the line connecting the plurality of emission points loins at least one of the first holders or the second holders by the joining material, and aligns the measured orientation of the curve of the optical elements with the measured orientation of the curve of the line connecting the plurality of emission points.

6. The method of manufacturing an optical module according to claim 4, wherein
each of the holder includes a third holder and a fourth holder to hold the collimating lens array by sandwiching the collimating lens array in a direction orthogonal to the orientation of the curve of the collimating lens array and the direction of propagation, and
the aligning the measured orientation of the curve of the collimating lens array with the measured orientation of the curve of the line connecting the plurality of emission points joins the third holder to the collimating lens array and the fourth holder to the collimating lens array, and aligns the measured orientation of the curve of the collimating lens array with the measured orientation of the curve of the line connecting the plurality of emission points.

7. The method of manufacturing an optical module according to claim 4, wherein
each of the holder includes a fifth holder and a sixth holder to hold the optical element by sandwiching the optical element in a direction orthogonal to the orientation of the curve of the optical elements and the direction of propagation, and
the aligning the measured orientation of the curve of the optical elements with the measured orientation of the curve of the line connecting the plurality of emission points, and joining each of the holder in the direction of propagation by a joining material joins the fifth holders by the joining material and the sixth holders by the joining material, and aligns the measured orientation of the curve of the optical elements with the measured orientation of the curve of the line connecting the plurality of emission points.
